(19) United States
(12) Patent Application Publication
(10) Pub. No.: US 2007/0241454 A1
(43) Pub. Date: Oct. 18, 2007

(54) CAPTURE RING

(76) Inventors: Jun-Ming Chen, Tainan City (TW); Wei-Ju Sun, Taoyuan County (TW); Shui-Yen Lu, Hsinchu County (TW); Ching-Shing Huang, Taipei City (TW); Yen-Hung Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,619

(22) Filed: Apr. 13, 2006

(51) Int. Cl. H01L 23/34

(52) U.S. Cl. 257/724

(57) ABSTRACT

A capture ring is provided. The capture ring has a top surface and a bottom surface. A support surface is located at the inner periphery of the capture ring parallel to the top surface for supporting a wafer. An inside diameter lead angle is located between the top surface and the support surface. There is an included angle between the inside diameter lead angle and a normal line of the support surface, wherein the included angle is more than 30 degrees but less than or equal to 90 degrees. Because the foregoing included angle is more than 30 degrees but less than or equal to 90 degrees, the refraction and reflecting area of plasma inside an etching machine will be increased. Therefore, the wafer bevel flake type defect size can be controlled and the wafer bevel defect count can be reduced.

### BACKGROUND OF THE INVENTION

1. Field of the Invention

The present invention relates to an etching machine. More particularly, the present invention relates to a capture ring within an etching machine.

2. Description of the Related Art

Dry etching is an anisotropic etching operation in which plasma is used as an etching source for patterning thin films on a semiconductor wafer.

However, some material will also be deposited on the peripheral area of the wafer in a thin film deposition process. If the material deposited in the peripheral area of the wafer is not removed in an etching process, some residues will remain on the wafer and may affect subsequent wafer deposition process and lead to wafer damage. For example, if metallic residues are left after a metallic layer etching operation, the subsequently deposited dielectric layer will have some metallic residues trapped underneath. In serious cases, some of the electrical properties of the semiconductor devices will be damaged.

### SUMMARY OF THE INVENTION

Accordingly, at least one objective of the present invention is to provide a capture ring that can improve wafer periphery defects or residual material condition.

To achieve these and other advantages and in accordance with the purpose of the invention, as embodied and broadly described herein, the invention provides a capture ring having a top surface and a bottom surface. A support surface is located at the inner periphery of the capture ring and set in parallel to the top surface for supporting a wafer. An inside diameter lead angle is located between the top surface and the support surface. There is an included angle between the inside diameter lead angle and a normal line of the support surface. One characteristic of the capture ring is that the included angle is more than 30 degrees but less than or equal to 90 degrees.

According to one preferred embodiment of the present invention, the aforementioned capture ring includes at least a circular groove located on the support surface.

According to one preferred embodiment of the present invention, the circular groove of the aforementioned capture ring has a depth of about 0.6 mm-0.6 mm, for example.

According to one preferred embodiment of the present invention, a distance is between the circular groove of the aforementioned capture ring and the bottom of the inside diameter lead angle.

According to one preferred embodiment of the present invention, the circular groove of the aforementioned capture ring and the inside diameter lead angle are linked.

According to one preferred embodiment of the present invention, the aforementioned capture ring is fabricated using ceramics, for example.

According to one preferred embodiment of the present invention, the aforementioned inside diameter lead angle can be an arc lead angle.

In the present invention, because the included angle between the inside diameter lead angle and a normal line of the carrier surface of the capture ring inside a plasma etching machine is greater than 30 degrees but smaller than 90 degrees, the plasma refraction/reflecting area is increased. Hence, the wafer bevel flake type defect size can be controlled and the wafer bevel defect count can be reduced. Furthermore, the present invention can reduce the amount of silicon ratio adjustment in a subsequent process and minimize process variations.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of a capture ring according to one embodiment of the present invention.

FIG. 2 is a schematic cross-sectional view along line II-II′ of FIG. 1.

FIGS. 3 through 7 are schematic cross-sectional views showing five types of capture rings according to the embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

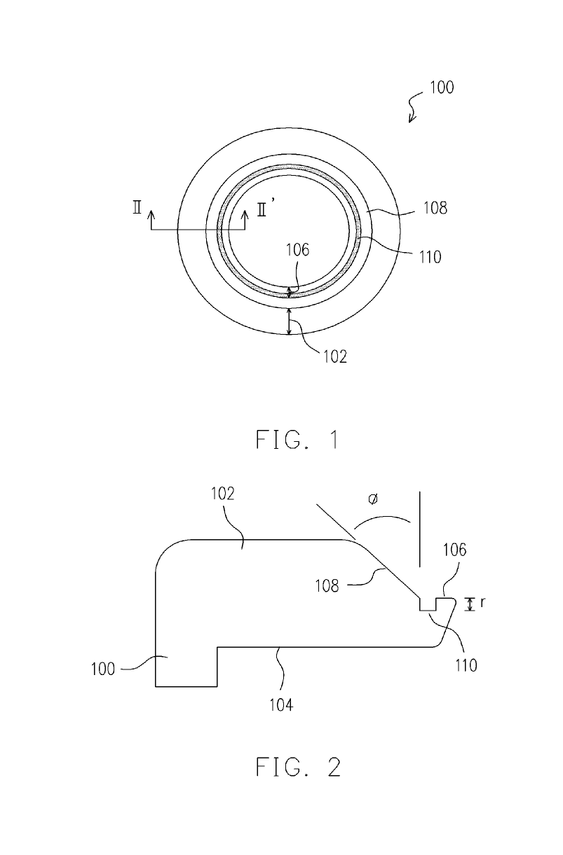

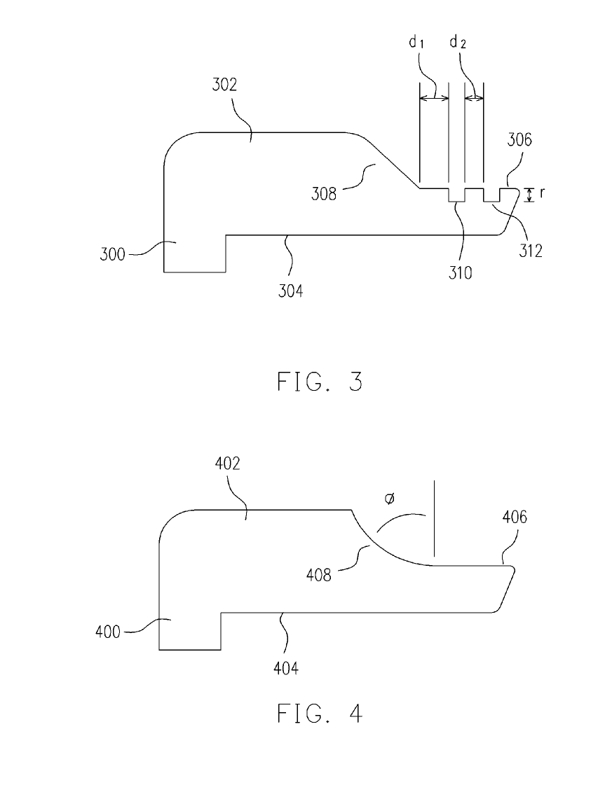

FIG. 1 is a top view of a capture ring according to one embodiment of the present invention. FIG. 2 is a schematic cross-sectional view along line II-II′ of FIG. 1. The capture ring 100 of the present embodiment shown in FIGS. 1 and 2 has a top surface 102 and a bottom surface 104 and is fabricated using ceramics, for example. The inner periphery of the capture ring 100 has a support surface 106. The support surface 106 is set parallel to the top surface 102 for supporting a wafer (not shown). There is an inside diameter lead angle 108 between the top surface 102 and the support surface 106. The inside diameter lead angle 108 and a normal line of the support surface 106 form an included angle ø. The included angle ø is greater than 30 degrees but smaller than or equal to 90 degrees. In addition, the capture ring 100 further includes at least a circular groove 110 disposed on the support surface 106. The circular groove 110 has a depth r of about 0.6 mm-1.6 mm, and the maximum of the depth r depends on mechanical strength of the material of the capture ring 100 so that the entire support surface 106 area of the capture ring 100 is free from any breaks.

Aside from the shape in FIG. 2, the present invention also includes some other variations such as the ones shown in FIGS. 3 to 7. FIGS. 3 through 7 are schematic cross-sectional views showing five types of capture rings according to the embodiment of the present invention.

As shown in FIG. 3, the capture ring 300 has a top surface 302 and a bottom surface 304 and fabricated using ceramics, for example. The inner periphery of the capture ring 300 has a support surface 306. The support surface 306 is set parallel to the top surface 302 for supporting a wafer (not shown). There is an inside diameter lead angle 308 between the top surface 302 and the support surface 306. The inside diameter lead angle 308 and a normal line of the support surface 306 form an included angle ø greater than 30 degrees but smaller than 90 degrees. Furthermore, the support surface 306 of the capture ring 300 has a first circular groove 310 and a second circuit groove 312. The space provided by the circuit grooves 310 and 312 serves to increase the gaseous exchange rate and enhance the etching rate of the wafer in the peripheral area. A distance d1 is between the first circular groove 310 and the bottom of the inside diameter lead angle 308. And, a distance d2 is between the second circular groove 312 and the first circular groove 310. In addition, the depth r of the first circular groove 310 and the second circular groove 312 is about 0.6 mm-1.6 mm, and the maximum of the depth r depends on mechanical strength of the material of the capture ring 300.

As shown in FIG. 4, the capture ring 400 has a top surface 402 and a bottom surface 404 and fabricated using ceramics, for example. The inner periphery of the capture ring 400 has a support surface 406. The support surface 406 is set parallel to the top surface 402 for supporting a wafer (not shown). There is an inside diameter lead angle 408 between the top surface 402 and the support surface 406. The inside diameter lead angle 408 is an arc lead angle. The inside diameter lead angle 408 and a normal line of the support surface 406 form an included angle ø. The included angle ø is greater than 30 degrees but smaller than 90 degrees. Furthermore, the capture ring 400 may also include more than one circular grooves (not shown) disposed on the support surface 406.

As shown in FIG. 5, the capture ring 500 has a top surface 502 and a bottom surface 504 and fabricated using ceramics, for example. The inner periphery of the capture ring 500 has a support surface 506. The support surface 506 is set parallel to the top surface 502 for supporting a wafer (not shown). There is an inside diameter lead angle 508 between the top surface 502 and the support surface 506. The inside diameter lead angle 508 is an arc lead angle. The inside diameter lead angle 508 and a normal line of the support surface 506 form an included angle ø. The included angle ø is greater than 30 degrees but smaller than 90 degrees. Furthermore, the capture ring 500 also includes a circular groove 510 disposed on the support surface 506. The circular groove 510 is linked to the bottom of the inside diameter lead angle 508. The circular groove 510 has a depth r of about 0.6 mm-1.6 mm, and the maximum of the depth r depends on mechanical strength of the material of the capture ring 500.

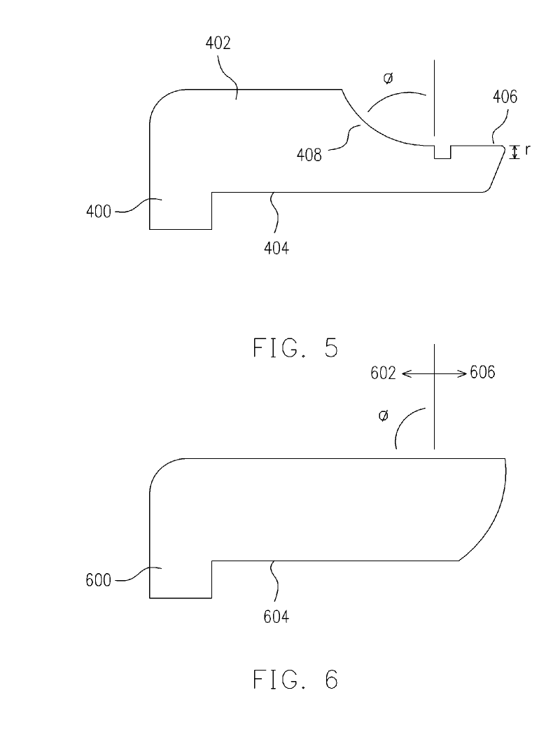

As shown in FIG. 6, the capture ring 600 has a top surface 602 and a bottom surface 604 and fabricated using ceramics, for example. The inner periphery of the capture ring 600 has a support surface 606 for supporting a wafer (not shown). In the present embodiment, the top surface 602 and the support surface 606 are coplanar and the angle ø is equal to 90 degrees.

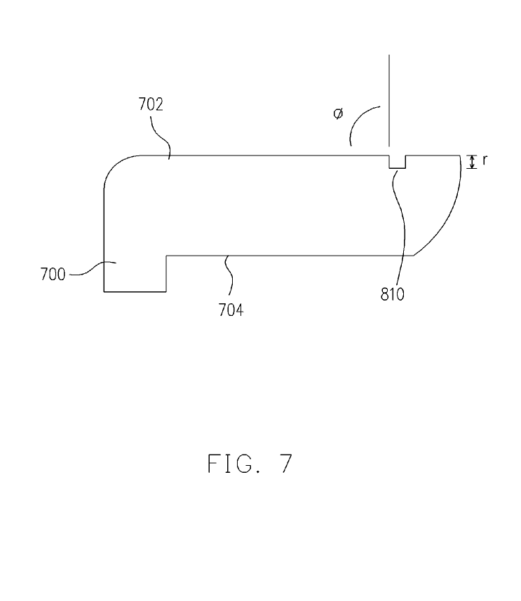

As shown in FIG. 7, the capture ring 700 has a top surface 702 and a bottom surface 704 and fabricated using ceramics, for example. The inner periphery of the capture ring 700 has a support surface 706 for supporting a wafer (not shown). In the present embodiment, the top surface 702 and the support surface 706 are coplanar and the angle ø is equal to 90 degrees. In addition, the capture ring 700 also includes at least one circular groove. In the present embodiment, a circular groove 710 is disposed on the support surface 706. The circular groove 710 has a depth r of about 0.6 mm-1.6 mm, and the maximum of the depth r depends on mechanical strength of the material of the capture ring 700.

As shown in FIGS. 6 and 7, even if the angle ø=90° and no mechanism is in place for refracting the plasma, the functional capacity to clear away all the residues deposited at the peripheral of the wafer can still achieved. This is because the increase in the air exchange rate when the wafer is placed on the support surface can still provide an effective means of etching away the residues at the peripheral region of the wafer.

In summary, the design in the present invention has at least the following advantages:

1. The angle in the capture ring is designed to be greater than 30 degrees but smaller than or equal to 90 degree so that the plasma refraction and reflection area are increased. Therefore, the wafer bevel flake type defect size can be controlled and the wafer bevel defect count can be reduced.

2. One or more circular grooves can be selectively formed on the support surface to increase plasma refraction and reflecting area so that the gas exchange rate is increased.

3. The amount of silicon ratio adjustment in a subsequent process can be reduced to minimize process variation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A capture ring having a top surface and a bottom surface, wherein an inner periphery of the capture ring has a support surface parallel to the top surface for supporting a wafer, the capture ring being characterized in that:
there is an inside diameter lead angle between the top surface of the capture ring and the support surface, wherein the inside diameter lead angle and a normal line of the support surface form an included angle greater than 30 degrees but smaller than or equal to 90 degrees.

2. The capture ring of claim 1, wherein the capture ring further includes at least a circular groove disposed on the support surface.

3. The capture ring of claim 2, wherein the circular groove has a depth of about 0.6 mm-1.6 mm.

4. The capture ring of claim 2, wherein a distance is between the circular groove and the bottom of the inside diameter lead angle.

5. The capture ring of claim 2, wherein the circular groove is linked to the bottom of the inside diameter lead angle.

6. The capture ring of claim 1, wherein the material constituting the capture ring includes ceramics.

7. The capture ring of claim 1, wherein the inside diameter lead angle includes an arc lead angle.
